(19) United States
(12) Patent Application Publication
(10) Pub. No.: US 2012/0316813 A1
(43) Pub. Date: Dec. 13, 2012

(54) METHOD AND DEVICE FOR PROVIDING RELIABLE INFORMATION ABOUT THE LIFETIME OF A BATTERY

(75) Inventor: Jochen Langheim, Viroflay (FR)

(73) Assignee: STMicroelectronics SA, Montrouge (FR)

(21) Appl. No.: 13/492,652

(22) Filed: Jun. 8, 2012

(30) Foreign Application Priority Data
Jun. 8, 2011 (FR) 1154994

(51) Int. Cl. G01R 31/36; G06F 19/00

(52) U.S. Cl. 702/63

(57) ABSTRACT

A battery powering a propulsion engine of a vehicle, is controlled by determining state data representative of the operation and wear of the battery, authenticating state data using an encryption method, and transmitting authenticated state data to an on-board computer of the vehicle for display.

### BACKGROUND

1. Technical Field

The present disclosure relates to the management of a rechargeable battery comprising a plurality of cells connected in series and possibly in parallel. The present disclosure applies, for example, but not exclusively to the batteries of electric or hybrid vehicles.

2. Description of the Related Art

An electric vehicle uses only an electric engine powered by a propulsion battery to be propelled. The propulsion battery of an electric vehicle is charged by a source of electrical energy external to the electric vehicle. A hybrid vehicle comprises both an electric engine and an internal combustion engine to be propelled. The electric engine of a hybrid vehicle is powered by a propulsion battery which is charged by the internal combustion engine. The propulsion battery of some hybrid vehicles may also be charged by a source of electrical energy external to the vehicle.

The propulsion battery of an electric or hybrid vehicle typically comprises several cells connected in series and possibly in parallel. Such a battery has a relatively high cost, which may reach half the price of the vehicle in which it is installed. When an electric or hybrid vehicle is put on for sale after some months or years of use, as a second-hand vehicle, the possible buyer of the vehicle must be able to evaluate the value of the vehicle. In vehicles with combustion engines, the odometer, which is secure, provides reliable information about the general wear of the vehicle. In electric or hybrid vehicles, the odometer allows only the part of the vehicle without the propulsion battery to be evaluated.

The result is that without reliable information about the wear of the battery, it is difficult to evaluate the value of a used electric or hybrid vehicle.

The lifetime of a battery depends on various parameters such as the number of charge and discharge cycles, the amplitude of each of these cycles, the temperature of the battery during charge cycles, etc. The various cells of a propulsion battery of electric or hybrid vehicles may have different behaviors and some of these cells may be faulty.

### BRIEF SUMMARY

It is desirable to be able to determine and display information allowing the state and lifetime of a propulsion battery of a vehicle, as well as the residual value of the battery to be evaluated. It is also desirable that the information displayed is reliable and may not be fraudulently handled.

Embodiments may relate to a method of controlling a battery powering a propulsion engine of a vehicle, comprising determining state data representative of the operation and wear of the battery, determining state data authenticable by applying an encryption method to the state data, and transmitting the authenticable state data to an on-board computer of the vehicle for them to be displayed.

According to one embodiment, the state data comprise a total amount of electrical energy supplied by the battery from its commissioning, and possibly, a number of faulty battery cells, a number of charge and discharge cycles, associated to the duration of each charge and discharge cycle, maximum and minimum measured temperatures, a date of commissioning of the battery, and an estimate of the remaining lifetime of the battery.

According to one embodiment, determining the authenticable state data comprises applying to the state data a symmetric encryption method using a secret data shared by the battery and the on-board computer, or an asymmetric encryption method, using a private key corresponding to a public key known by the on-board computer.

According to one embodiment, the battery comprises several battery modules, each comprising a group of at least one battery cell, the method comprising determining the state data representative of the operation and wear of each battery module, and transmitting to a process unit of the battery the state data of each battery module, the state data representative of the operation and wear of the battery being determined by the battery process unit from the state data of each battery module.

According to one embodiment, the state data of each battery module are transmitted to the battery process unit in authenticable form, the method comprising applying by each battery module to the state data of the battery module a symmetric encryption method using secret data shared by the battery module and the battery process unit, or an asymmetric encryption method using a private key corresponding to a public key known by the battery process unit.

According to one embodiment, the state data representative of the operation and wear of each battery module are transmitted to the battery process unit, by a wireless transmission link.

Embodiments also may relate to a battery powering a propulsion engine of a vehicle, comprising a data process unit connected to sensors providing measures of operating parameters of the battery, the process unit being configured to implement methods according to the disclosure.

According to one embodiment, the battery comprises several battery modules, each battery module comprising a group of at least one battery cell, and a module process unit configured to determine state data of the group of cells, and transmit the state data to the battery process unit.

According to one embodiment, the process unit of each battery module is configured to apply to the state data representative of the operation and wear of the group of cells of the battery module, a symmetric encryption method using secret data shared by the module process unit and the battery process unit, or an asymmetric encryption method using a private key corresponding to a public key known by the battery process unit.

According to one embodiment, each battery module comprises a wireless transmission circuit connected to the module process unit for transmitting state data of the module to the battery process unit.

According to one embodiment, each battery module comprises at least a current sensor, a voltage sensor, an impedance sensor, a temperature sensor, a pressure sensor, a vibration or humidity sensor, connected to the module process unit.

In an embodiment, a method comprises determining state data representative of operation and wear of a battery to power a propulsion engine of a vehicle, the state data including an indication of an amount of electrical energy previously supplied from the battery; authenticating determined state data using encryption; and transmitting authenticated state data to an on-board computer of the vehicle to display. In an embodiment, the amount of energy is a total amount of electrical energy supplied by the battery since commissioning of the battery, and the state data includes at least one of: a number of faulty battery cells; a number of charge and discharge cycles, associated to the duration of each charge and discharge cycle; maximum and minimum measured temperatures; a date of commissioning of the battery; and an estimate of a remaining lifetime of the battery. In an embodiment, the authenticating determined state data comprises applying to the state data at least one of a symmetric encryption method using a secret data shared by the battery and the on-board computer; and an asymmetric encryption method, using a private key corresponding to a public key known by the on-board computer. In an embodiment, the battery comprises several battery modules, each comprising a group of at least one battery cell, the method comprising determining state data representative of operation and wear of each battery module, and transmitting to a process unit of the battery state data of each battery module, the state data representative of operation and wear of the battery being determined by the process unit from the state data of each battery module. In an embodiment, state data of each battery module are transmitted to the process unit in authenticable form, the method comprising applying by each battery module to state data of the battery module at least one of a symmetric encryption method using secret data shared by the battery module and the battery process unit; and an asymmetric encryption method using a private key corresponding to a public key known by the battery process unit. In an embodiment, the state data representative of the operation and wear of each battery module are transmitted to the battery process unit, by a wireless transmission link.

In an embodiment, a battery comprises one or more sensors configured to measure operating parameters of the battery, wherein the battery is configured to provide power to a propulsion engine of a vehicle; and one or more processing devices configured to: determine state data representative of operation and wear of the battery, the state data including an indication of an amount of electrical energy previously supplied from the battery; authenticate determined state data using encryption; and transmit authenticated state data to an on-board computer of the vehicle to display. In an embodiment, the battery comprises several battery modules, each battery module comprising a group of at least one battery cell, wherein the one or more processing devices include a battery process unit and a module process unit of each battery module configured to determine state data of the group of cells, and to transmit the state data of the group of cells to the battery process unit. In an embodiment, the module process unit of each battery module is configured to apply to state data representative of the operation and wear of the group of cells of the battery module, at least one of a symmetric encryption method using secret data shared by the module process unit and the battery process unit; and an asymmetric encryption method using a private key corresponding to a public key known by the battery process unit. In an embodiment, each battery module comprises a wireless transmission circuit connected to the module process unit and configured to transmit state data of the module to the battery process unit. In an embodiment, each battery module comprises at least a current sensor, a voltage sensor, an impedance sensor, a temperature sensor, a pressure sensor, and a vibration or humidity sensor, connected to the module process unit. In an embodiment, the amount of energy is a total amount of electrical energy supplied by the battery since commissioning of the battery.

In an embodiment, a system comprises: means for determining state data representative of operation and wear of a power supply to power a propulsion engine of a vehicle, the state data including an indication of an amount of electrical energy previously supplied from the power supply; means for authenticating determined state data using encryption; and means for transmitting authenticated state data to an on-board computer of the vehicle to display. In an embodiment, the system comprises the power supply. In an embodiment, the power supply is a battery. In an embodiment, the system comprises means for wirelessly transmitting data from the means for determining state data. In an embodiment, the system comprises the propulsion engine. In an embodiment, the amount of energy is a total amount of electrical energy supplied by the battery since commissioning of the battery.

In an embodiment, a non-transitory computer-readable medium's contents configure a computing system to perform a method, the method comprising: determining state data representative of operation and wear of a battery to power a propulsion engine of a vehicle, the state data including an indication of an amount of electrical energy previously supplied from the battery;

authenticating determined state data using encryption; and transmitting authenticated state data to an on-board computer of the vehicle to display. In an embodiment, the method further comprises wirelessly transmitting the determined state data.

### BRIEF DESCRIPTION OF THE SEVERAL VIEWS OF THE DRAWINGS

Embodiments will be described hereinafter, in relation with, but not limited to the appended figures wherein:

FIG. 1 schematically shows a propulsion battery of an electric or hybrid vehicle, according to one embodiment;

FIG. 2 schematically shows a cell of the propulsion battery, according to one embodiment;

FIG. 3 schematically shows an architecture of the propulsion battery, according to one embodiment;

FIG. 4 schematically shows an architecture of the propulsion battery, according to another embodiment;

### DETAILED DESCRIPTION

In the following description, numerous specific details are given to provide a thorough understanding of embodiments. The embodiments can be practiced without one or more of the specific details, or with other methods, components, materials, etc. In other instances, well-known structures, materials, or operations, such as, for example, battery cells, processor cores, etc., are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” “according to an embodiment” or “in an embodiment” and similar phrases in various places throughout this specification are not necessarily all referring to the same embodiment. Furthermore, the particular features, structures, or characteristics may be combined in any suitable manner in one or more embodiments.

The headings provided herein are for convenience only and do not interpret the scope or meaning of the embodiments.

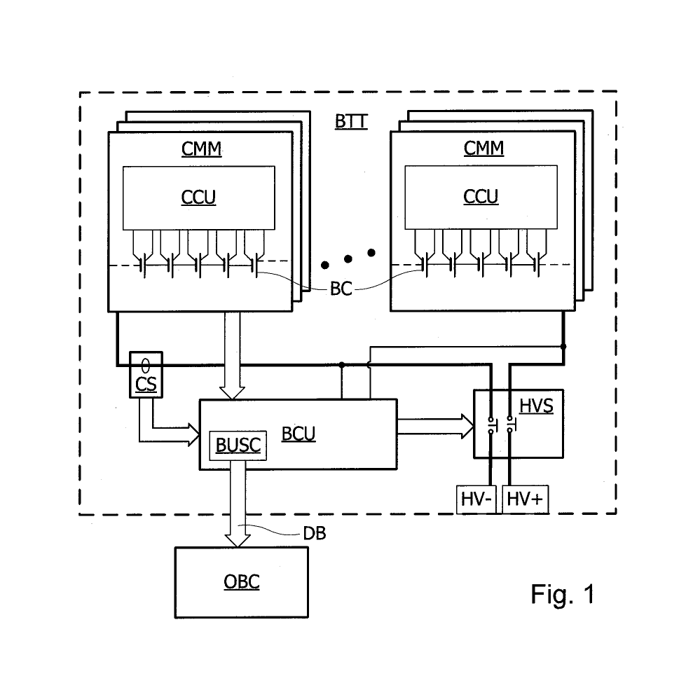

FIG. 1 schematically shows a propulsion battery BTT of an electric or hybrid vehicle. The battery BTT comprises several battery cell modules CMM, a central control unit BCU of the battery, and a high voltage switch HVS. The switch HVS is connected between cells BC of the battery BTT and external connection terminals HV−, HV+ of the battery BTT. Each cell module CMM comprises one or more battery cells BC connected in series, and a cell control unit CCU. The control unit CCU monitors the state and operation and each cell BC of the module CMM. The unit CCU may also balance each cell BC. The central unit BCU receives from the units CCU measures relating to the operation of each cell BC. The central unit BCU may be connected to a current sensor CS to receive a measure of the intensity of the current supplied by the battery BTT, and controls the switch HVS. The central unit BCU comprises a communication interface BUSC, for example a bus controller for transmitting information about the battery BTT such as a charge state of the battery. In a vehicle, the interface BUSC may be connected to an on-board computer OBC, for example through a bus DB of CAN type (Controller Area Network). The modules CMM can be separated from the battery BTT in order to allow modules CMM comprising a faulty cell to be replaced.

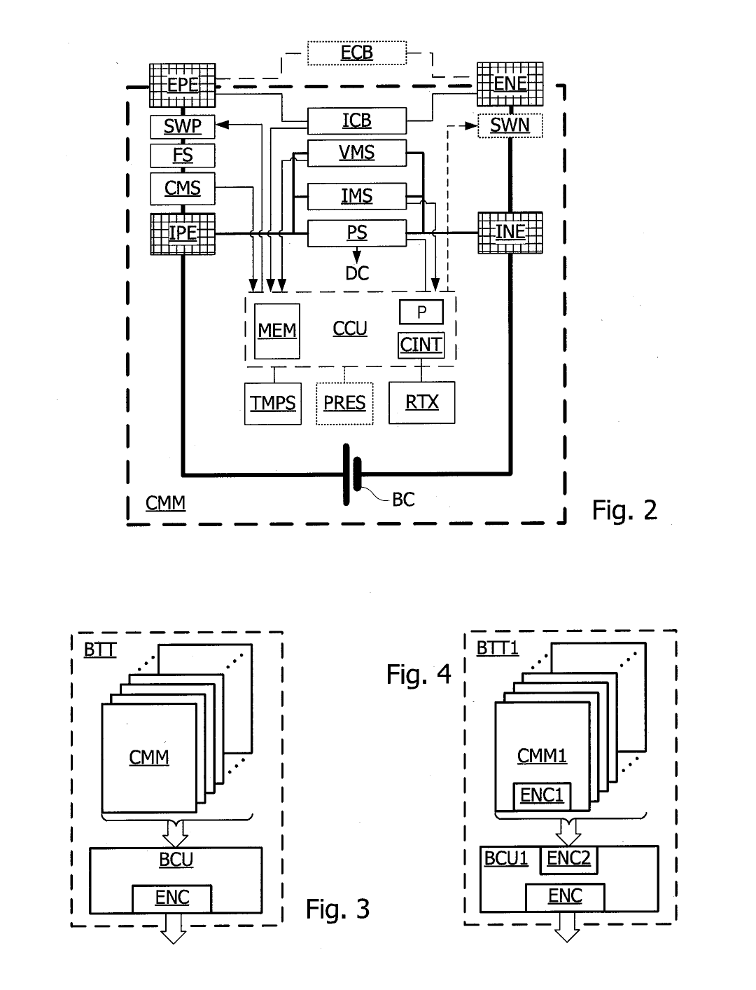

FIG. 2 shows a cell module CMM and the control unit CCU thereof. In the example of FIG. 2, the module CMM comprises a single battery cell BC comprising internal positive IPE and negative INE terminals. Some embodiments of the module CMM may comprise a plurality of cells BC. The positive terminal IPE is connected to a current intensity sensor CMS which is connected to a protection fuse FS. The fuse FS is connected to an external positive terminal EPE for connecting the cell BC through a switch SWP. The negative terminal INE is also connected to an external negative terminal ENE for connecting the cell BC, possibly through a switch SWN.

The module CMM also comprises an internal power supply circuit PS, and impedance measurement IMS and voltage measurement VMS circuits, connected between the terminals IPE and INE. The module CMM may also comprise an internal balancing circuit ICB connected between the terminals EPE and ENE. This circuit may be replaced by an external balancing circuit ECB.

The control unit CCU of the module CMM which may comprise a microcontroller or other processing devices or circuitry P, is powered by the circuit PS, and is connected to a temperature sensor TMPS and possibly to a pressure sensor PRES, providing temperature and pressure measures of the cell BC. The unit CCU comprises a memory MEM and possibly a communication interface CINT connected to a wireless transmission circuit, for example of radiofrequency or Bluetooth type, to communicate with the central unit BCU. Admittedly, the connection between the unit CCU of each module BCU and the unit BCU may be wired. The unit CCU is configured to determine charge and operating states of each cell of the module CMM, from the measures provided by the sensors CMS, VMS, IMS, TMPS and PRES, and to control the switches SWP and SWN of each cell as a function of the operating state of the cell. Each module CMM may also comprise humidity and vibration sensors connected to the unit CCU.

The unit CCU may memorize in its memory MEM a battery module identifier CMM, event logs, and battery cell operating patterns, to determine with the measures received a lifetime of the cell or cells to which it is connected. The charge and operating states of the cell or group of cells BC of the module CMM, determined by the unit CCU are transmitted to the unit BCU which determines from the cell states received, charge and operating states of the battery BTT.

It is to be noted that the charge and operating state of each cell may be determined by the unit BCU alone as a function of measures provided by the modules CMM, in particular if the modules CMM cannot be separated from the battery BTT.

The unit BCU may be configured to count a number a charge and discharge cycles of the battery, determine minimum and maximum temperatures and pressures measured by the sensors TMPS, PRES of the modules CMM, and count the faulty cells BC. The unit BCU may also memorize amplitudes or depths of the charges and discharges of the battery or compute an average depth of charge and an average depth of discharge. The unit BCU may also memorize a commissioning date of the battery. The unit BCU may be configured to evaluate a wear or lifetime, or a residual value of the battery as a function of the measures provided by the units CCU of the modules CMM and the data it stores.

To that end, the unit BCU may be configured to periodically measure the intensity of the current and the voltage across the battery BTT when the battery is discharging, to calculate an amount of electrical energy supplied during each period, by multiplying the current intensity measure by the voltage measure and by the period duration. The unit BCU may be configured to periodically determine the internal impedance of the battery using the current and voltage measured across the battery. The amount of electrical energy obtained for the period is used to increment at each period a counter of energy supplying a total amount of electrical energy supplied by the battery BTT. The amount of electrical energy calculated for a period may be corrected by various factors such as a temperature factor deriving from the battery temperature and depending on the type of battery.

The periodic calculation of the amount of electrical energy supplied by the battery may also be performed by the modules CMM for each cell BC of the battery, the amounts of energy supplied, obtained for each cell being transmitted to the unit BCU to increment the counter of total electrical energy supplied by the battery.

The unit BCU may be configured to compute and update an estimation of the residual value or lifetime of the battery as a function of at least two of the following parameters:
the total energy supplied by the battery from its commissioning date,
the internal impedance of the battery,
the average depths of the charges and/or discharges of the battery,
the time from the commissioning date of the battery,
an average temperature when the battery is in use, and
the number of faulty cells of the battery.

The value of the counter of total energy supplied by the battery BTT and/or the residual value or lifetime of the battery may be memorized in a non-volatile and secure memory (i.e., protected against fraudulent access) connected to or integrated into the unit BCU. Likewise, all the data transmitted by the unit BCU for example to the on-board computer OBC and allowing the operating and wear state (and/or the residual value) of the battery to be evaluated may be stored in such a secure memory.

In addition, if the modules CMM can be separated from the battery BTT, the counter of the amount of electrical energy supplied may be securely managed and memorized by the unit CCU of each module CMM, and reset to 0 before the first commissioning of the module CMM. The unit CCU of each module CMM periodically transmits the value of its counter of energy to the unit BCU. The unit BCU then calculates at each period the total amount of electrical energy supplied by the battery BTT, by adding all the energy counter values received from the units CCU for the period. Thus, if a module CMM of the battery BTT is replaced by a new module, the total amount of electrical energy calculated by the unit BCU after replacing the module CMM may be lower than the total amount of energy before the replacement.

FIG. 3 shows the architecture of the battery BTT when the modules CMM cannot be separated from the battery. To guarantee the authenticity of the state data relating to the battery BTT provided by the unit BCU, the unit BCU comprises an encryption module ENO configured to generate from the state data, authenticable state data which are transmitted to the vehicle on-board computer OBC. The computer OBC is then provided with an encryption module adapted to determine the authenticity of the battery BTT and the state data of the battery BTT, transmitted by the unit BCU. To that end, the on-board computer shares a secret key with the unit BCU.

According to one embodiment, the module ENC is configured to calculate a signature of the state data of the battery and to transmit the calculated signature in association with the state data to the computer OBC. The signature may be calculated using a symmetric encryption method, using a secret key shared with the computer OBC or an asymmetric encryption method, using a private key of the unit BCU corresponding to a public key known by the computer OBC. According to another embodiment, the module ENC is configured to cipher the state data of the battery and to transmit the state data under ciphered form to the computer OBC. The state data may be ciphered using a secret key shared with the computer OBC or a private key of the unit BCU corresponding to a public key known by the computer.

A unique identifier allowing the battery BTT to be identified is stored in a secure memory connected to the unit BCU. At powering up, the computer OBC sends to the unit BCU an authentication command and an authentication challenge (for example a random number). In the case of a symmetric encryption method, the unit BCU sends in response an identifier of the battery BTT, with the authentication challenge ciphered using a secret key shared with the computer OBC. The secret key may be generated by the computer OBC and by the unit BCU using a key derivation encryption function applied to the identifier of the battery BTT and so-called “master” secret data initially introduced into a secure memory connected to the computer OBC and the secure memory connected to the unit BCU. The secret key thus generated may then be used to cipher the data transmitted by the unit BCU to the computer OBC. In the case of an asymmetric encryption method, the unit BCU ciphers the challenge received with a private key and sends the ciphered result obtained to the computer OBC, with the public key associated to the private key, possibly signed by a certificate emitted by a trusted authority. The computer OBC checks the authenticity of the public key using the certificate, and checks the ciphered challenge received by deciphering it using the public key received and by comparing it to the challenge it has sent to the unit BCU.

The battery is considered as authentic if the deciphered challenge corresponds to the challenge transmitted to the unit BCU. In the event of failure of battery authentication by the computer OBC, the latter may take any adapted measure, for example displaying a message on a display of the instrument panel.

In the event of battery replacement, the previous procedure executed at powering up the computer OBC allows it and the unit BCU to determine encryption keys required to secure the data emitted by the unit BCU. It may be provided that the computer OBC accesses to a remote server to check that the battery identifier received belongs to a list of authorized identifiers. If the identifier is not authorized, a warning may be displayed on a display of the vehicle.

FIG. 4 shows the architecture of a battery BTT1 comprising battery modules CMM1 which can be separated from the battery BTT1. The battery BTT1 also comprises a central unit for controlling the battery BCU1 which provides to the vehicle on-board computer data relating to the battery state and wear (and/or residual value). Each module CMM1 differs from the module CMM in that it comprises an encryption module ENC1 configured to generate from the state data produced by the unit CCU, authenticable state data which are transmitted to the unit BCU1, to guarantee the authenticity of the data relating to the battery BTT1 provided by each module CMM1. The unit BCU1 differs from the unit BCU in that it comprises an encryption module ENC2 to check the authenticity of the modules CMM1, as well as that of the state data of cells BC received from these modules. In addition, data transmission between the unit BCU1 and the computer OBC may be performed in the same way as with the battery BTT.

A unique identifier allowing each battery module CMM1 to be identified is securely memorized in a secure memory connected to the unit CCU of the module CCM1. Each time the battery is used and/or charged, the authentication procedure previously described between the unit BCU and the computer OBC may be executed between the unit BCU1 and the unit CCU of each module CCM1. At the end of the authentication of each module CCM1, the unit BCU thus memorizes an identifier and a secret key or a public key of each module CCM1, this key then being used to secure the data transmitted by the units CCU to the unit BCU. The identifiers of each module CCM1 may also be transmitted by the unit BCU to the computer OBC to be checked by a remote server, for example each time a change of module CCM1 identifier is detected, indicating that module replacement has been performed in the battery.

It will be clear to those skilled in the art that the present disclosure is susceptible of various embodiments and applications. In particular, the disclosure is not limited to the battery architectures mentioned in the above description. The disclosure also applies to a battery comprising a single process unit connected to sensors measuring electrical parameters (voltage, current intensity, impedance) at the electrical connection terminals of the battery.

The operating and wear state and the residual value of the battery may also be evaluated based on other parameters than a total amount of energy supplied, for example based on variations of current intensity or voltage across the battery or each cell of the battery.

Some embodiments may take the form of computer program products. For example, according to one embodiment there is provided a computer readable medium comprising a computer program adapted to perform one or more of the methods described above. The medium may be a physical storage medium such as for example a Read Only Memory (ROM) chip, or a disk such as a Digital Versatile Disk (DVD-ROM), Compact Disk (CD-ROM), a hard disk, a memory, a network, or a portable media article to be read by an appropriate drive or via an appropriate connection, including as encoded in one or more barcodes or other related codes stored on one or more such computer-readable mediums and being readable by an appropriate reader device.

Furthermore, in some embodiments, some or all of the systems and/or modules may be implemented or provided in other manners, such as at least partially in firmware and/or hardware, including, but not limited to, one or more application-specific integrated circuits (ASICs), discrete circuitry, standard integrated circuits, controllers (e.g., by executing appropriate instructions, and including microcontrollers and/or embedded controllers), field-programmable gate arrays (FPGAs), complex programmable logic devices (CPLDs), etc., as well as devices that employ RFID technology. In some embodiments, some of the modules or controllers separately described herein may be combined, split into further modules and/or split and recombined in various manners.

The systems, modules and data structures may also be transmitted as generated data signals (e.g., as part of a carrier wave) on a variety of computer-readable transmission mediums, including wireless-based and wired/cable-based mediums.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
determining state data representative of operation and wear of a battery to power a propulsion engine of a vehicle, the state data including an indication of an amount of electrical energy previously supplied from the battery, and/or an estimate of a remaining lifetime of the battery;
authenticating determined state data using encryption; and
transmitting authenticated state data to an on-board computer of the vehicle to display.

2. The method of claim 1 wherein the amount of energy is a total amount of electrical energy supplied by the battery since commissioning of the battery, and the state data includes at least one of: a number of faulty battery cells; a number of charge and discharge cycles, associated to the duration of each charge and discharge cycle; maximum and minimum measured temperatures; a date of commissioning of the battery.

3. The method of claim 1 wherein the estimate of the remaining lifetime of the battery is computed as a function of at least two of the following parameters:
the total amount of energy supplied by the battery from its commissioning date,
an internal impedance of the battery,
an average depth of charges and/or discharges of the battery,
a time from the commissioning date of the battery,
an average temperature when the battery is in use, and
a number of faulty cells of the battery.

4. The method of claim 1 wherein the authenticating determined state data comprises applying to the state data at least one of a symmetric encryption method using a secret data shared by the battery and the on-board computer; and an asymmetric encryption method, using a private key corresponding to a public key known by the on-board computer.

5. The method of claim 1 wherein the battery comprises several battery modules, each comprising a group of at least one battery cell, the method comprising determining state data representative of operation and wear of each battery module, and transmitting to a process unit of the battery state data of each battery module, the state data representative of operation and wear of the battery being determined by the process unit from the state data of each battery module.

6. The method of claim 5 wherein state data of each battery module are transmitted to the process unit in authenticable form, the method comprising applying by each battery module to state data of the battery module at least one of a symmetric encryption method using secret data shared by the battery module and the battery process unit; and an asymmetric encryption method using a private key corresponding to a public key known by the battery process unit.

7. The method of claim 5 wherein the state data representative of the operation and wear of each battery module are transmitted to the battery process unit, by a wireless transmission link.

8. A battery, comprising:
one or more sensors configured to measure operating parameters of the battery, wherein the battery is configured to provide power to a propulsion engine of a vehicle; and
one or more processing devices configured to:
determine state data representative of operation and wear of the battery, the state data including an indication of an amount of electrical energy previously supplied from the battery, and/or an estimate of a remaining lifetime of the battery;
authenticate determined state data using encryption; and
transmit authenticated state data to an on-board computer of the vehicle to display.

9. The battery of claim 8 wherein one processing device of the battery is configured to compute the estimate of the remaining lifetime of the battery as a function of at least two of the following parameters:
the total amount of energy supplied by the battery from its commissioning date,
an internal impedance of the battery,
an average depth of charges and/or discharges of the battery,
a time from the commissioning date of the battery,
an average temperature when the battery is in use, and
a number of faulty cells of the battery.

10. The battery of claim 8, comprising several battery modules, each battery module comprising a group of at least one battery cell, wherein the one or more processing devices include a battery process unit and a module process unit of each battery module configured to determine state data of the group of cells, and to transmit the state data of the group of cells to the battery process unit.

11. The battery of claim 9 wherein the module process unit of each battery module is configured to apply to state data representative of the operation and wear of the group of cells of the battery module, at least one of a symmetric encryption method using secret data shared by the module process unit and the battery process unit; and an asymmetric encryption method using a private key corresponding to a public key known by the battery process unit.

12. The battery of claim 9 wherein each battery module comprises a wireless transmission circuit connected to the module process unit and configured to transmit state data of the module to the battery process unit.

13. The battery of claim 9 wherein each battery module comprises at least a current sensor, a voltage sensor, an impedance sensor, a temperature sensor, a pressure sensor, and a vibration or humidity sensor, connected to the module process unit.

14. The battery of claim 9 wherein the amount of energy is a total amount of electrical energy supplied by the battery since commissioning of the battery.

15. A system, comprising:
means for determining state data representative of operation and wear of a power supply to power a propulsion engine of a vehicle, the state data including an indication of an amount of electrical energy previously supplied from the power supply, and/or an estimate of a remaining lifetime of the power supply;
means for authenticating determined state data using encryption; and
means for transmitting authenticated state data to an on-board computer of the vehicle to display.

16. The battery of claim 15 wherein the means for determining state data are configured to compute the estimate of the remaining lifetime of the power supply as a function of at least two of the following parameters:
the total amount of energy supplied by the power supply from its commissioning date,
an internal impedance of the power supply,
an average depth of charges and/or discharges of the power supply,
a time from the commissioning date of the power supply,
an average temperature when the power supply is in use, and a number of faulty cells of the power supply.

17. The system of claim 15, further comprising the power supply.

18. The system of claim 16 wherein the power supply is a battery.

19. The system of claim 17, further comprising means for wirelessly transmitting data from the means for determining state data.

20. The system of claim 16, further comprising the propulsion engine.

21. The system of claim 17 wherein the amount of energy is a total amount of electrical energy supplied by the battery since commissioning of the battery.

22. A non-transitory computer-readable medium whose contents configure a computing system to perform a method, the method comprising:
determining state data representative of operation and wear of a battery to power a propulsion engine of a vehicle, the state data including an indication of an amount of electrical energy previously supplied from the battery, and/or an estimate of a remaining lifetime of the battery;
authenticating determined state data using encryption; and
transmitting authenticated state data to an on-board computer of the vehicle to display.

23. The method of claim 22 wherein the estimate of the remaining lifetime of the battery is computed as a function of at least two of the following parameters:
the total amount of energy supplied by the battery from its commissioning date,
an internal impedance of the battery,
an average depth of charges and/or discharges of the battery,
a time from the commissioning date of the battery,
an average temperature when the battery is in use, and
a number of faulty cells of the battery.

24. The non-transitory computer-readable medium of claim 22 wherein the method further comprises wirelessly transmitting the determined state data.
